(19) United States
(12) Patent Application Publication
(10) Pub. No.: US 2026/0093173 A1
(43) Pub. Date: Apr. 2, 2026

(54) EXTREME ULTRAVIOLET LITHOGRAPHY MASK PELLICLE INSPECTION DEVICE

(71) Applicant: Shanghai Institute of Optics and Fine Mechanics, Chinese Academy of Sciences, Shanghai (CN)

(72) Inventors: Nan LIN, Shanghai (CN); Jing CAO, Shanghai (CN); Ziyi ZHANG, Shanghai (CN)

(21) Appl. No.: 19/275,946

(22) Filed: Jul. 21, 2025

(30) Foreign Application Priority Data
Sep. 27, 2024 (CN) 202411360924.2

(51) Int. Cl. G03F 1/84; G03F 1/62

(52) U.S. Cl. CPC G03F 1/84; G03F 1/62

(57) ABSTRACT

Pellicle inspection device for extreme ultraviolet lithography masks comprises inspection light source module to generate light source with wavelength in extreme ultraviolet band and equipped with extreme ultraviolet irradiation time control electronic shutter and light source transmission system; sample platform module in vacuum chamber to fix, move and rotate sample to switch between different performance tests of pellicle and achieve irradiation of extreme ultraviolet light source at different positions and angles of incidence on pellicle; module for detecting impact of contaminants on mask imaging to study impact of different types and sizes of contaminants below 50 μm and distance between pellicle and mask on mask imaging and determine optimal distance; module for measuring transmissivity, transmittance uniformity, and reflectivity of pellicle to measure optical properties of pellicle at different angles of incidence and study impact of chemical changes of pellicle on optical properties.

### CROSS-REFERENCE TO RELATED APPLICATIONS

The subject application claims priority on Chinese Patent Application No. CN202411360924.2 filed on Sep. 27, 2024 in China. The contents and subject matters of the Chinese priority application are incorporated herein by reference in the entirety.

### TECHNICAL FIELD

The present invention belongs to the field of extreme ultraviolet lithography technology and specifically relates to an extreme ultraviolet lithography mask pellicle inspection device. The device can be used for research on the impact of contaminants on the pellicle on mask imaging, chemical changes of the pellicle under extreme ultraviolet light irradiation (comprising studies of chemical reactions between the pellicle and hydrogen), measurement of pellicle transmissivity, transmission uniformity, and reflectivity, as well as the development of new pellicle materials.

### BACKGROUND ART

Extreme Ultraviolet Lithography (EUVL) is a key technology for the mass production of chips at and below the 7-nanometer technology node. Compared to traditional transmissive Deep Ultraviolet (DUV) mask technology, EUVL employs a reflective mask design, which poses stricter requirements for process control, material development, and mask measurement.

During the EUVL process, any minor contamination on the mask surface can cause severe pattern defects, thereby affecting the final quality of the chip. To address the issue, pellicle technology has been introduced. The pellicle is an ultra-thin film (tens of nanometers thick, suspended over a range of tens of centimeters) that maintains a certain distance from the mask. The design not only prevents particles in the environment from falling onto the mask pattern but also keeps contaminants out of the focal plane, reducing their impact on imaging and thus minimizing printing defects. However, for larger-sized contaminants, such as large particles, they can still significantly affect pattern formation even when out of focus. Therefore, a device is needed to study the impact of different types and sizes of contaminants on EUVL imaging and to determine the optimal distance between the pellicle and the mask.

EUVL technology sets comprehensive and high-standard requirements for pellicle performance, comprising but not limited to excellent optical properties (high transmissivity, uniform transmission distribution, and low reflectivity), outstanding thermal and chemical stability, and hydrogen radical durability.

As extreme ultraviolet light is strongly absorbed by almost all materials, the pellicles used in deep ultraviolet lithography masks cannot meet the requirements of EUVL, forcing the industry to urgently develop a new pellicle material system and measure its optical properties (transmissivity, transmission uniformity, and reflectivity). Among the candidate materials, silicon, zirconium disilicide, and carbon materials (such as carbon nanotubes and nanometer-thick graphite films) have shown potential for application. In particular, nanometer-thick graphite films have shown excellent performance in terms of light transmissivity and mechanical strength, but their reactivity with hydrogen poses a significant challenge. Therefore, it is crucial to conduct an in-depth analysis of the chemical reaction mechanism between hydrogen and nanometer-thick graphite film-based pellicles in the EUVL environment.

Moreover, EUV masks typically use oblique incidence (e.g., the chief ray angle at the object is usually 6°), and with the development of high numerical aperture (e.g., 0.55NA) EUVL, the incidence angle on the mask is also increasing. Therefore, it is necessary to quickly and efficiently detect the changes in the optical properties (transmissivity, transmission uniformity, and reflectivity) of the pellicle at different incidence angles, especially at large incidence angles, as well as the chemical changes that may occur to the pellicle under EUV irradiation and their specific impact on optical properties.

### SUMMARY OF THE INVENTION

To overcome the disadvantages of the existing technologies, the present invention provides an extreme ultraviolet lithography mask pellicle inspection device, which solves the problems mentioned in the background technology regarding the impact of different types and sizes of contaminants on the pellicle and the influence of the distance between the pellicle and the mask on mask imaging. The present invention is applicable to different types of contaminants, namely particles and stains, different sizes of contaminants, namely those below 50 μm, and the distance between the pellicle and the mask, with an adjustable distance range of 1 to 10 mm. Through the present invention, the relationship between the type and size of contaminants and the distance between the pellicle and the mask can be studied to determine the optimal distance.

In the present invention, the optical properties of the pellicle (i.e., transmissivity, transmission uniformity, and reflectivity) are measured at different incident angles, with an adjustable angle range of 5° to 25°. While testing the optical properties of the pellicle (i.e., transmissivity, transmission uniformity, and reflectivity), the impact of chemical changes in the pellicle on its optical properties (i.e., transmissivity, transmission uniformity, and reflectivity) is also studied. The device comprises a hydrogen production module that can control the hydrogen partial pressure in the device's vacuum chamber, with an adjustable range of 0 to 10 Pa. The present invention allows for the study of the chemical reactions between the pellicle and hydrogen under extreme ultraviolet irradiation, especially the chemical changes in pellicles based on carbon materials, to meet the needs of new pellicle material development.

The technical solution adopted by the present invention to achieve the above objectives is as follows.

The present invention provides an extreme ultraviolet lithography mask pellicle inspection device, comprising:
an inspection light source module used to generate the extreme ultraviolet light source required for inspection with a wavelength in the extreme ultraviolet band, and equipped with an extreme ultraviolet irradiation time control electronic shutter to control the irradiation time, as well as a light source transmission system;
a sample platform module, placed inside a vacuum chamber, used to fix, move, and rotate the pellicle and mask samples to be tested to ensure that the extreme ultraviolet light source achieves irradiation at different positions and different incident angles, where the distance between the pellicle and the mask is adjustable within the range of 1 to 10 mm;
a module for detecting the impact of contaminants on the pellicle on mask imaging, used to study the impact of different types and sizes of contaminants below 50 μm, as well as the distance between the pellicle and the mask, on mask imaging, and to determine the optimal distance;
a module for measuring the transmissivity, transmission uniformity, and reflectivity of the pellicle, used to measure the optical properties of the pellicle at different incident angles and to study the impact of chemical changes in the pellicle on its optical properties, and the adjustable range of the incident angle is 5 to 25°. The pellicle is fixed on the pellicle holder, and the position of the pellicle is adjusted by the first electric three-axis displacement table. The mask is fixed on the mask holder, and the position of the mask is adjusted by the second electric three-axis displacement table. Both the first and second electric three-axis displacement tables are fixed on the electric rotation displacement table and are placed in sequence along the direction of the inspection light propagation.

In the present invention, for the detection of the impact of contaminants on the pellicle on mask imaging, the sample is the pellicle and the mask. The sample platform module simultaneously places the pellicle and the mask for synchronized fixation, movement, and rotation. Along the direction of the inspection light propagation, the mask is placed behind the pellicle. By controlling the rotation of the electric rotation displacement table, the pellicle and the mask are synchronously rotated to a preset incident angle to ensure the best mask imaging at the preset incident angle. By adjusting the first electric three-axis displacement table to change the distance between the pellicle and the mask within the range of 1 to 10 mm, the impact of contaminants on mask imaging at different distances between the pellicle and the mask is studied. The relationship between the distance and the impact of contaminants on mask imaging is obtained, and the optimal distance between the pellicle and the mask is provided.

In the present invention, for the measurement of the transmissivity, transmission uniformity, and reflectivity of the pellicle, the sample is the pellicle. The sample platform module is used for the fixation, movement, and rotation of the pellicle. The irradiation position of the extreme ultraviolet light on the pellicle is always located on the rotation axis of the electric rotation displacement table. By rotating the electric rotation displacement table, measurements at different incident angles of the pellicle are achieved, with an adjustable angle range of 5 to 25°. By adjusting the first electric three-axis displacement table, measurements at different positions of the pellicle are realized.

In the present invention, preferably, the sample platform module comprises: a pellicle holder for placing the pellicle and a mask holder for placing the mask. The pellicle holder is controlled by the first electric three-axis displacement table, and the mask holder is controlled by the second electric three-axis displacement table. Both the first and second electric three-axis displacement tables are fixed on the electric rotation displacement table and are placed in sequence along the direction of the inspection light propagation.

In the present invention, preferably, the light source transmission system comprises a toroidal mirror or two cylindrical mirrors.

In the present invention, depending on the two functions of detecting the impact of contaminants on the pellicle on mask imaging and measuring the transmissivity, transmission uniformity, and reflectivity of the pellicle, the sample placement is divided into two ways.

In the present invention, for the detection of the impact of contaminants on the pellicle on mask imaging, the sample is the pellicle and the mask. The sample platform module simultaneously places the pellicle and the mask for fixation, movement, and rotation. Along the direction of the inspection light propagation, the mask is placed behind the pellicle. By controlling the rotation of the electric rotation displacement table, the pellicle and the mask are synchronously rotated to a given incident angle. At this given incident angle, the mask imaging is optimal. By adjusting the first electric three-axis displacement table to change the distance between the pellicle and the mask within the range of 1 to 10 mm, the impact of contaminants on mask imaging at different distances between the pellicle and the mask is studied. The relationship between the distance and the impact of contaminants on mask imaging is obtained, and the optimal distance between the pellicle and the mask is provided.

In the present invention, for the measurement of the transmissivity, transmission uniformity, and reflectivity of the pellicle, the sample is the pellicle. The sample platform module is used for the fixation, movement, and rotation of the pellicle. The irradiation position of the extreme ultraviolet light on the pellicle is always located on the rotation axis of the electric rotation displacement table. By rotating the electric rotation displacement table, measurements at different incident angles of the pellicle are achieved, with an adjustable angle range of 5 to 25°. By adjusting the first electric three-axis displacement table, measurements at different positions of the pellicle are realized.

In the present invention, the module for detecting the impact of contaminants on the pellicle on mask imaging is used to study the impact of different types and sizes of contaminants below 50 μm and the distance between the pellicle and the mask within the range of 1 to 10 mm on mask imaging. Depending on the inspection purpose, it is divided into two modes.

In the present invention, the first mode is used to obtain the mask pattern and its defect diffraction signals, comprising a projection optical system and an extreme ultraviolet camera.

In the present invention, the second mode involves exposing the photoresist to the inspection light source module and then developing it. The developed pattern is characterized and analyzed using a scanning electron microscope or atomic force microscope to assess the impact of contaminants on the mask exposure pattern. The impact comprises the type of defects, the number of defects, line width, line width roughness, and line edge roughness. It comprises a projection optical system and a wafer coated with photoresist.

In the present invention, the module for measuring the transmissivity, transmission uniformity, and reflectivity of the pellicle is divided into two modes based on whether the transmissivity, and reflectivity are measured simultaneously.

In the present invention, the first mode uses two detectors to measure the energy of the transmitted and reflected beams separately, enabling synchronous measurement of the pellicle's transmissivity, transmission uniformity, and reflectivity. It comprises a first detector, a second detector, a first circular arc rail, and a first electric slider. The axis of the first circular arc rail coincides with the axis of the electric rotation displacement table, with a central angle of 60°. The first detector is fixed on the first electric slider, which is on the first circular arc rail, positioned in the direction of the reflected beam. By rotating the sample by an angle α, the first detector rotates by 2α to detect the energy of the reflected beam. The second detector is fixed in the direction of the transmitted beam. Without a sample, it can detect the energy of the incident light beam from the inspection light source. With a sample, rotating the electric rotation displacement table allows measurement.

### BRIEF DESCRIPTION OF THE DRAWINGS

FIG. 1 shows the structure of one embodiment of the extreme ultraviolet lithography mask pellicle inspection device according to the present invention.

FIG. 2 shows the first mode of the pellicle transmissivity, transmission uniformity, and reflectivity measurement module in the extreme ultraviolet lithography mask pellicle inspection device according to the present invention (with a toroidal mirror for light source transmission and the first mode of the module for detecting the impact of contaminants on the pellicle on mask imaging).

FIG. 3 shows the first mode of the pellicle transmissivity, transmission uniformity, and reflectivity measurement module in the extreme ultraviolet lithography mask pellicle inspection device according to the present invention (with a toroidal mirror for light source transmission and the second mode of the module for detecting the impact of contaminants on the pellicle on mask imaging).

FIG. 4 shows the first mode of the pellicle transmissivity, transmission uniformity, and reflectivity measurement module in the extreme ultraviolet lithography mask pellicle inspection device according to the present invention (with two cylindrical mirrors for light source transmission and the first mode of the module for detecting the impact of contaminants on the pellicle on mask imaging).

FIG. 5 shows the first mode of the pellicle transmissivity, transmission uniformity, and reflectivity measurement module in the extreme ultraviolet lithography mask pellicle inspection device according to the present invention (with two cylindrical mirrors for light source transmission and the second mode of the module for detecting the impact of contaminants on the pellicle on mask imaging).

FIG. 6 shows the second mode of the pellicle transmissivity, transmission uniformity, and reflectivity measurement module in the extreme ultraviolet lithography mask pellicle inspection device according to the present invention (with a toroidal mirror for light source transmission and the first mode of the module for detecting the impact of contaminants on the pellicle on mask imaging).

FIG. 7 shows the second mode of the pellicle transmissivity, transmission uniformity, and reflectivity measurement module in the extreme ultraviolet lithography mask pellicle inspection device according to the present invention (with a toroidal mirror for light source transmission and the second mode of the module for detecting the impact of contaminants on the pellicle on mask imaging).

FIG. 8 shows the second mode of the pellicle transmissivity, transmission uniformity, and reflectivity measurement module in the extreme ultraviolet lithography mask pellicle inspection device according to the present invention (with two cylindrical mirrors for light source transmission and the first mode of the module for detecting the impact of contaminants on the pellicle on mask imaging).

FIG. 9 shows the second mode of the pellicle transmissivity, transmission uniformity, and reflectivity measurement module in the extreme ultraviolet lithography mask pellicle inspection device according to the present invention (with two cylindrical mirrors for light source transmission and the second mode of the module for detecting the impact of contaminants on the pellicle on mask imaging).

FIG. 10 shows the first mode of the module for detecting the impact of contaminants on the pellicle on mask imaging in the extreme ultraviolet lithography mask pellicle inspection device according to the present invention (with a toroidal mirror for light source transmission and the first mode of the pellicle transmissivity, transmission uniformity, and reflectivity measurement module).

FIG. 11 shows the first mode of the module for detecting the impact of contaminants on the pellicle on mask imaging in the extreme ultraviolet lithography mask pellicle inspection device according to the present invention (with two cylindrical mirrors for light source transmission and the first mode of the pellicle transmissivity, transmission uniformity, and reflectivity measurement module).

FIG. 12 shows the first mode of the module for detecting the impact of contaminants on the pellicle on mask imaging in the extreme ultraviolet lithography mask pellicle inspection device according to the present invention (with a toroidal mirror for light source transmission and the second mode of the pellicle transmissivity, transmission uniformity, and reflectivity measurement module).

FIG. 13 shows the first mode of the module for detecting the impact of contaminants on the pellicle on mask imaging in the extreme ultraviolet lithography mask pellicle inspection device according to the present invention (with two cylindrical mirrors for light source transmission and the second mode of the pellicle transmissivity, transmission uniformity, and reflectivity measurement module).

FIG. 14 shows the second mode of the module for detecting the impact of contaminants on the pellicle on mask imaging in the extreme ultraviolet lithography mask pellicle inspection device according to the present invention (with a toroidal mirror for light source transmission and the first mode of the pellicle transmissivity, transmission uniformity, and reflectivity measurement module).

FIG. 15 shows the second mode of the module for detecting the impact of contaminants on the pellicle on mask imaging in the extreme ultraviolet lithography mask pellicle inspection device according to the present invention (with two cylindrical mirrors for light source transmission and the first mode of the pellicle transmissivity, transmission uniformity, and reflectivity measurement module).

FIG. 16 shows the second mode of the module for detecting the impact of contaminants on the pellicle on mask imaging in the extreme ultraviolet lithography mask pellicle inspection device according to the present invention (with a toroidal mirror for light source transmission and the second mode of the pellicle transmissivity, transmission uniformity, and reflectivity measurement module).

FIG. 17 shows the second mode of the module for detecting the impact of contaminants on the pellicle on mask imaging in the extreme ultraviolet lithography mask pellicle inspection device according to the present invention (with two cylindrical mirrors for light source transmission and the second mode of the pellicle transmissivity, transmission uniformity, and reflectivity measurement module).

The reference numbers in the figures refer to the following structures, components, or steps:
201—extreme ultraviolet light source; 202—extreme ultraviolet irradiation time control electronic shutter; 203—toroidal mirror; 204—pellicle; 205—pellicle holder; 206—first electric three-axis displacement table; 207—mask holder; 208—second electric three-axis displacement table; 209—electric rotation displacement table; 210—first detector; 211—first electric slider; 212—first circular arc rail; 213—second detector; 214—hydrogen production module; 215—chemical detection and analysis module; 216—projection optical system; 217—extreme ultraviolet cameral;
301—extreme ultraviolet light source; 302—extreme ultraviolet irradiation time control electronic shutter; 303—toroidal mirror; 304—pellicle; 305—pellicle holder; 306—first electric three-axis displacement table; 307—mask holder; 308—second electric three-axis displacement table; 309—electric rotation displacement table; 310—first detector; 311—first electric slider; 312—first circular arc rail; 313—second detector; 314—hydrogen production module; 315—chemical detection and analysis module; 316—projection optical system; 317—wafer coated with photoresist;
401—extreme ultraviolet light source; 402—extreme ultraviolet irradiation time control electronic shutter; 403—first cylindrical mirror; 404—second cylindrical mirror; 405—pellicle 406—pellicle holder; 407—first electric three-axis displacement table; 408—mask holder 409—second electric three-axis displacement table; 410—electric rotation displacement table; 411—first detector; 412—first electric slider; 413—first circular arc rail; 414—second detector; 415—hydrogen production module; 416—chemical detection and analysis module; 417—projection optical system; 418—extreme ultraviolet camera;
501—extreme ultraviolet light source; 502—extreme ultraviolet irradiation time control electronic shutter; 503—first cylindrical mirror; 504—second cylindrical mirror; 505—pellicle; 506—pellicle holder; 507—first electric three-axis displacement table; 508—mask holder; 509—second electric three-axis displacement table; 510—electric rotation displacement table; 511—first detector; 512—first electric slider; 513—first circular arc rail; 514—second detector; 515—hydrogen production module; 516—chemical detection and analysis module; 517—projection optical system; 518—wafer coated with photoresist;
601—extreme ultraviolet light source; 602—extreme ultraviolet irradiation time control electronic shutter; 603—toroidal mirror; 604—pellicle; 605—pellicle holder; 606—first electric three-axis displacement table; 607—mask holder; 608—second electric three-axis displacement table; 609—electric rotation displacement table; 610—third detector; 611—second electric slider; 612—second circular arc rail; 613—hydrogen production module; 614—chemical detection and analysis module; 615—projection optical system; 616—extreme ultraviolet camera;
701—extreme ultraviolet light source; 702—extreme ultraviolet irradiation time control electronic shutter; 703—toroidal mirror; 704—pellicle; 705—pellicle holder; 706—first electric three-axis displacement table; 707—mask holder; 708—second electric three-axis displacement table; 709—electric rotation displacement table; 710—third detector; 711—second electric slider 712—second circular arc rail; 713—hydrogen production module; 714—chemical detection and analysis module; 715—projection optical system; 716—wafer coated with photoresist;
801—extreme ultraviolet light source; 802—extreme ultraviolet irradiation time control electronic shutter; 803—first cylindrical mirror; 804—second cylindrical mirror; 805—pellicle; 806—pellicle holder; 807—first electric three-axis displacement table; 808—mask holder; 809—second electric three-axis displacement table; 810—electric rotation displacement table; 811—third detector; 812—second electric slider; 813—second circular arc rail; 814—hydrogen production module; 815—chemical detection and analysis module; 816—projection optical system; 817—extreme ultraviolet camera;
901—extreme ultraviolet light source; 902—extreme ultraviolet irradiation time control electronic shutter; 903—first cylindrical mirror; 904—second cylindrical mirror; 905—pellicle; 906—pellicle holder; 907—first electric three-axis displacement table; 908—mask holder; 909—second electric three-axis displacement table; 910—electric rotation displacement table; 911—third detector; 912—second electric slider; 913—second circular arc rail; 914—hydrogen production module; 915—chemical detection and analysis module; 916—projection optical system; 917—wafer coated with photoresist;
1001—extreme ultraviolet light source; 1002—extreme ultraviolet irradiation time control electronic shutter; 1003—toroidal mirror; 1004—pellicle; 1005—pellicle holder; 1006—first electric three-axis displacement table; 1007—mask; 1008—mask holder; 1009—second electric three-axis displacement table; 1010—electric rotation displacement table; 1011—projection optical system; 1012—extreme ultraviolet camera; 1013—hydrogen production module; 1014—chemical detection and analysis module; 1015—first detector; 1016—first electric slider; 1017—first circular arc rail; 1018—second detector;
1101—extreme ultraviolet light source; 1102—extreme ultraviolet irradiation time control electronic shutter; 1103—first cylindrical mirror; 1104—second cylindrical mirror; 1105—pellicle; 1106—pellicle holder; 1107—first electric three-axis displacement table; 1108—mask; 1109—mask holder; 1110—second electric three-axis displacement table; 1111—electric rotation displacement table; 1112—projection optical system; 1113—extreme ultraviolet camera; 1114—hydrogen production module; 1115—chemical detection and analysis module; 1116—first detector; 1117—first electric slider; 1118—first circular arc rail; 1119—second detector;
1201—extreme ultraviolet light source; 1202—extreme ultraviolet irradiation time control electronic shutter; 1203—toroidal mirror; 1204—pellicle; 1205—pellicle holder; 1206—first electric three-axis displacement table; 1207—mask; 1208—mask holder; 1209—second electric three-axis displacement table; 1210—electric rotation displacement table; 1211—projection optical system; 1212—extreme ultraviolet camera; 1213—hydrogen production module; 1214—chemical detection and analysis module; 1215—third detector; 1216—second electric slider; 1217—second circular arc rail;
1301—extreme ultraviolet light source; 1302—extreme ultraviolet irradiation time control electronic shutter; 1303—first cylindrical mirror; 1304—second cylindrical mirror; 1305—pellicle; 1306—pellicle holder; 1307—first electric three-axis displacement table; 1308—mask; 1309—mask holder; 1310—second electric three-axis displacement table; 1311—electric rotation displacement table; 1312—projection optical system; 1313—extreme ultraviolet camera; 1314—hydrogen production module; 1315—chemical detection and analysis module; 1316—third detector; 1317—second electric slider; 1318—second circular arc rail;
1401—extreme ultraviolet light source; 1402—extreme ultraviolet irradiation time control electronic shutter; 1403—toroidal mirror; 1404—pellicle; 1405—pellicle holder; 1406—first electric three-axis displacement table; 1407—mask; 1408—mask holder; 1409—second electric three-axis displacement table; 1410—electric rotation displacement table; 1411—projection optical system; 1412—wafer coated with photoresist; 1413—hydrogen production module; 1414—chemical detection and analysis module; 1415—first detector; 1416—first electric slider; 1417—first circular arc rail; 1418—second detector;
1501—extreme ultraviolet light source; 1502—extreme ultraviolet irradiation time control electronic shutter; 1503—first cylindrical mirror; 1504—second cylindrical mirror; 1505—pellicle; 1506—pellicle holder; 1507—first electric three-axis displacement table; 1508—mask; 1509—mask holder; 1510—second electric three-axis displacement table; 1511—electric rotation displacement table; 1512—projection optical system; 1513—wafer coated with photoresist; 1514—hydrogen production module; 1515—chemical detection and analysis module; 1516—first detector; 1517—first electric slider; 1518—first circular arc rail; 1519—second detector;
1601—extreme ultraviolet light source; 1602—extreme ultraviolet irradiation time control electronic shutter; 1603—toroidal mirror; 1604—pellicle; 1605—pellicle holder; 1606—first electric three-axis displacement table; 1607—mask; 1608—mask holder; 1609—second electric three-axis displacement table; 1610—electric rotation displacement table; 1611—projection optical system; 1612—wafer coated with photoresist; 1613—hydrogen production module; 1614—chemical detection and analysis module; 1615—third detector; 1616—second electric slider; 1617—second circular arc rail;
1701—extreme ultraviolet light source; 1702—extreme ultraviolet irradiation time control electronic shutter; 1703—first cylindrical mirror; 1704—second cylindrical mirror; 1705—pellicle; 1706—pellicle holder; 1707—first electric three-axis displacement table; 1708—mask; 1709—mask holder; 1710—second electric three-axis displacement table; 1711—electric rotation displacement table; 1712—projection optical system; 1713—wafer coated with photoresist; 1714—hydrogen production module; 1715—chemical detection and analysis module; 1716—third detector; 1717—second electric slider; 1718—second circular arc rail.

### DETAILED DESCRIPTION OF THE INVENTION

The following is a further elaboration of the present invention in conjunction with the embodiments and the accompanying drawings. The present invention can be realized in many different forms and should not be construed as limiting the scope of protection of the present invention. The terms used in the specification of this application are intended to describe specific embodiments and are not intended to limit this application.

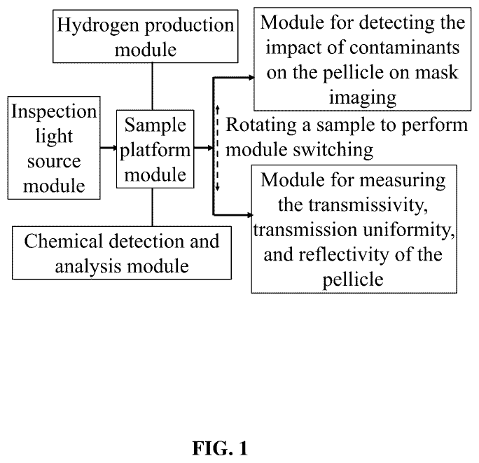

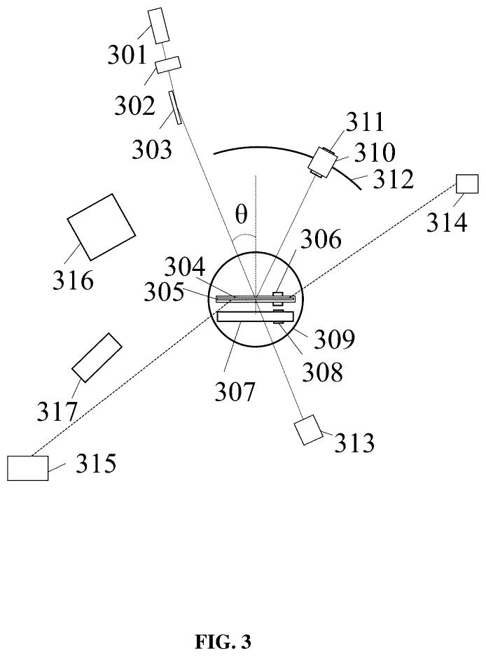

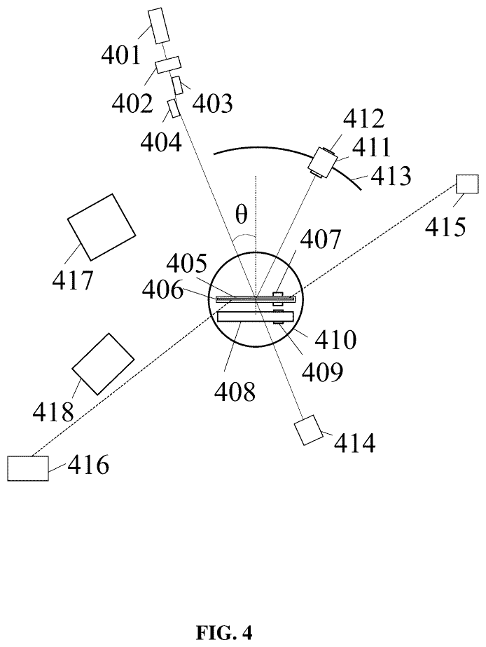

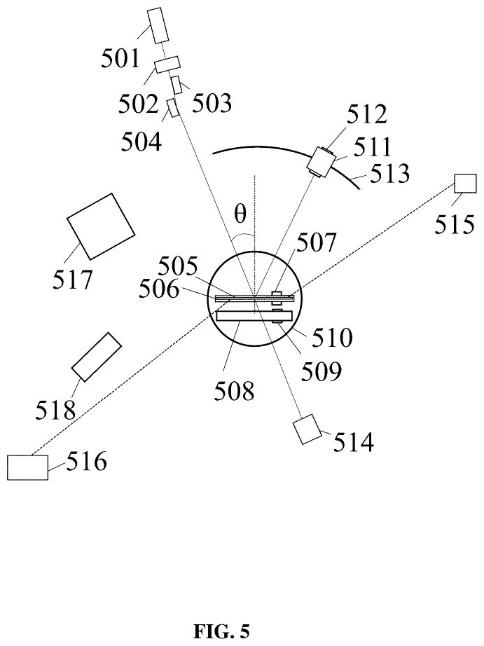

The generation method of the present invention is illustrated in FIGS. 1 to 17 with the reference numbers, and the container and auxiliary system design is as follows.

FIG. 1 is a flowchart of one embodiment of the extreme ultraviolet lithography mask pellicle inspection device according to the present invention, which comprises an inspection light source module, a sample platform module, a module for detecting the impact of contaminants on the pellicle on mask imaging, a module for measuring the transmissivity, transmission uniformity, and reflectivity of the pellicle, a hydrogen production module, and a chemical detection and analysis module. By rotating the sample, the device can switch between the module for detecting the impact of contaminants on the pellicle on mask imaging and the module for measuring the transmissivity, transmission uniformity, and reflectivity of the pellicle.

The inspection light source module provides an extreme ultraviolet light source with a wavelength in the range of 10 to 20 nm, which is used to generate the extreme ultraviolet light required for inspection.

The sample platform module is used for the fixation, movement, and rotation of the sample, allowing the extreme ultraviolet light to irradiate the sample at different positions and angles. In the module for measuring the transmissivity, transmission uniformity, and reflectivity of the pellicle, the sample is the pellicle. The sample platform module is used to fix, move, and rotate the pellicle, allowing the extreme ultraviolet light to irradiate the pellicle at different incident angles, with an adjustable angle range of 5 to 25°, and at different positions. For each measurement of the pellicle's transmissivity, transmission uniformity, and reflectivity, the irradiation position of the extreme ultraviolet light on the pellicle is always located on the rotation axis of the electric rotation displacement table. In the module for detecting the impact of contaminants on the pellicle on mask imaging, the sample is the pellicle and the mask. The sample platform module is used to fix, move, and rotate the pellicle and the mask, allowing the extreme ultraviolet light to irradiate the pellicle and the mask at a given incident angle, under which the mask imaging is optimal.

The module for detecting the impact of contaminants on the pellicle on mask imaging introduces different types of contaminants, namely particles and stains, and contaminants of different sizes, with sizes below 50 μm, to study the impact of different types and sizes of contaminants on mask imaging. The distance between the pellicle and the mask is adjustable within the range of 1 to 10 mm, allowing for the study of the impact of the distance between the pellicle and the mask on mask imaging, and providing the relationship between the distance and mask imaging, as well as the optimal distance between the pellicle and the mask. The module for detecting the impact of contaminants on the pellicle on mask imaging operates in two modes. The first mode comprises a projection optical system and an extreme ultraviolet camera, used to obtain the mask pattern and its defect diffraction signals. Considering that the transfer of the mask pattern to the photoresist also depends on the type of photoresist and subsequent processes, such as development, post-bake temperature, and time, the second mode comprises a projection optical system and a wafer coated with photoresist. After exposure to extreme ultraviolet light, the photoresist is developed, and the developed pattern is characterized and analyzed using a scanning electron microscope or atomic force microscope to assess the impact of contaminants on the lithography pattern. The impact comprises the type of defects, the number of defects, line width, line width roughness, and line edge roughness. This mode can be used to study the impact of development conditions, post-bake temperature, and time on the lithography pattern.

In the present invention, the pellicle transmissivity, transmission uniformity, and reflectivity measurement module is used to measure the extreme ultraviolet transmissivity, transmission uniformity, and reflectivity of the pellicle at different incident angles, with an adjustable angle range of 5 to 25°. When used in conjunction with the chemical detection and analysis module, it can be employed to study the relationship between the chemical changes in the pellicle under extreme ultraviolet irradiation and its optical properties, namely transmissivity, transmission uniformity, and reflectivity.

In the present invention, the hydrogen production module is designed to produce hydrogen and can control the hydrogen partial pressure in the device's vacuum chamber, with an adjustable range of 0 to 10 Pa.

In the present invention, the chemical detection and analysis module is used to detect and analyze the chemical changes in the pellicle under extreme ultraviolet irradiation, comprising the chemical reactions between the pellicle and the aforementioned hydrogen. Specific detection and analysis are carried out using mass spectrometry and/or Raman spectroscopy. The device can simultaneously perform chemical detection and analysis as well as research on the optical properties of the pellicle.

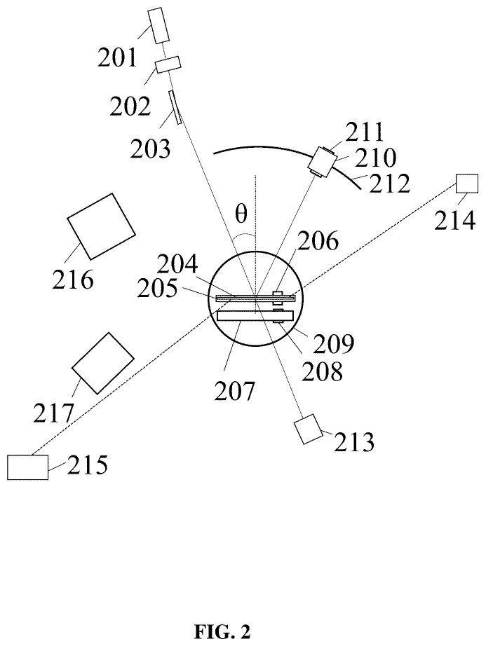

FIG. 2 is a diagram of the first mode of the pellicle transmissivity, transmission uniformity, and reflectivity measurement module in the extreme ultraviolet lithography mask pellicle inspection device according to the present invention (with a toroidal mirror for light source transmission and the first mode of the module for detecting the impact of contaminants on the pellicle on mask imaging).

The operation process of the device is as follows. Extreme ultraviolet light from the source (201) passes through the extreme ultraviolet irradiation time control electronic shutter (202) and reaches the light source transmission system, which is a toroidal mirror (203). The light is then directed onto the pellicle (204), which is mounted on the pellicle holder (205). The pellicle holder (205) is attached to the first electric three-axis displacement table (206), which is fixed on the electric rotation displacement table (209). The irradiation position of the extreme ultraviolet light on the pellicle is always located on the rotation axis of the electric rotation displacement table (209). By rotating the electric rotation displacement table (209), measurements of the pellicle (204) are taken at different incident angles (θ), with an adjustable range of 5-25°. The first electric three-axis displacement table (206) can be adjusted to measure different positions on the pellicle (204). The mask holder (207) is mounted on the second electric three-axis displacement table (208), which is also fixed on the electric rotation displacement table (209). In the module for measuring the transmissivity, transmission uniformity, and reflectivity of the pellicle, no mask is placed. The mask holder (207) does not obstruct the transmitted light after the pellicle (204).

In the present invention, the measurement of pellicle transmissivity, transmission uniformity, and reflectivity in the first mode is conducted, where the first mode of the pellicle transmissivity, transmission uniformity, and reflectivity measurement module is used to measure these properties. The energy of the transmitted and reflected beams is detected using two detectors, allowing for simultaneous measurement of the pellicle's transmissivity and reflectivity. This comprises the first detector (210), the first electric slider (211), the first circular arc rail (212), and the second detector (213). The center of the first circular arc rail (212) coincides with the axis of the sample electric rotation displacement table (209), with a central angle of 60°. The first detector (210) is fixed on the first electric slider (211), which is on the first circular arc rail (212), positioned in the direction of the reflected beam. By rotating the sample by an angle α, the first detector (210) rotates by 2α to detect the energy of the reflected beam. The second detector (213) is fixed in the direction of the transmitted beam. Without a sample, it can detect the incident light intensity from the inspection light source. With the pellicle (204) in place, rotating the electric rotation displacement table (209) allows for the measurement of the sample's transmitted beam energy at different incident angles. The pellicle's reflectivity is calculated by the ratio of the reflected beam energy to the incident beam energy, and its transmissivity is calculated by the ratio of the transmitted beam energy to the incident beam energy. By adjusting the first electric three-axis displacement table (206) to change the sample measurement position, multiple-point transmissivity measurements of the pellicle are achieved, yielding the pellicle's transmission uniformity.

The specific process for measuring the transmissivity and reflectivity of the pellicle is as follows: first, without placing the pellicle, the light intensity measured by the second detector (213) is I₀. Then, the pellicle (204) is mounted on the pellicle holder (205). The pellicle holder (205) is secured onto the first electric three-axis displacement table (206). By adjusting the position of the pellicle (204) using the first electric three-axis displacement table (206), the inspection light is made to irradiate the desired location on the pellicle. Each time the pellicle position is adjusted, it is necessary to ensure that the irradiation position of the extreme ultraviolet light on the pellicle is on the rotation axis of the electric rotation displacement table (209). The pellicle (204) is then rotated using the electric rotation displacement table (209) to achieve the desired incident angle (θ₀), the light intensity is measured by the first detector (210) as Iᵣ_{₀}, the light intensity is measured by the second detector (213) as Iₜ_{₀}, at the aforementioned incident angle (θ₀), under the aforementioned incident angle, the pellicle reflectivity is calculated as Iᵣ_{₀}/I₀, the pellicle transmissivity is calculated as Iₜ_{₀}/I₀.

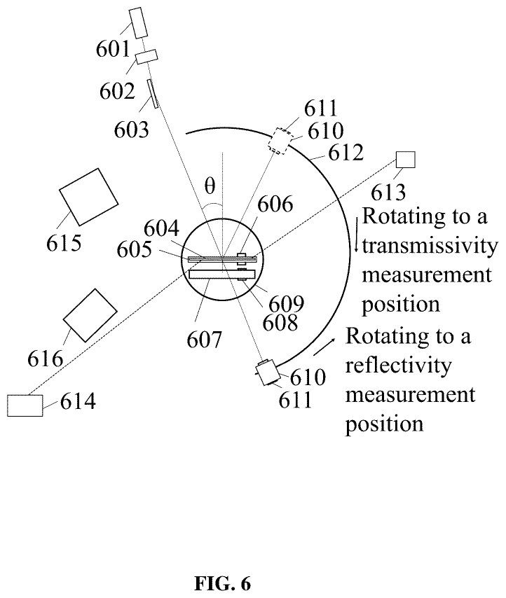

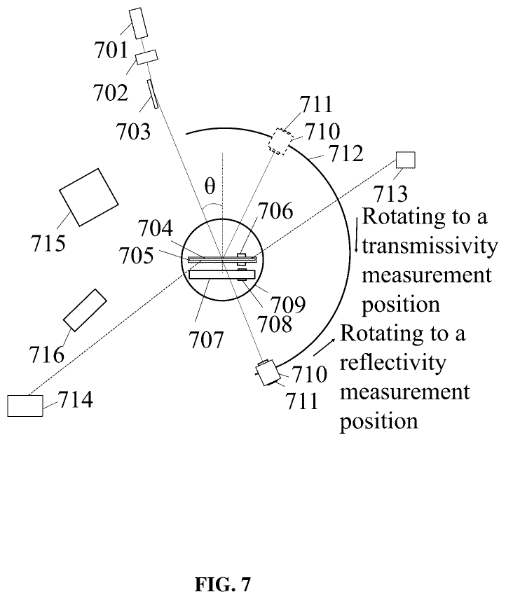

By adjusting the first electric three-axis displacement table (206), measurements are taken at different positions of the pellicle (204). Each time the position of the pellicle is adjusted, it is necessary to ensure that the irradiation position of the extreme ultraviolet light on the pellicle is on the rotation axis of the electric rotation displacement table (209). The transmitted light intensity at different positions of the pellicle (204) is measured using the second detector (213). (Iₜ_{₁}, Iₜ_{₂}, Iₜ_{₃} . . . Iₜ_{ₙ} where n is the number of the measurement position), the transmissivity at each position is calculated as Iₜ_{ₙ}/I₀ by rotating the pellicle (204) using the electric rotation displacement table (209), different incident angles are obtained. The transmissivity and reflectivity of the pellicle at these different incident angles can be measured, allowing for the study of the pellicle's transmission uniformity (θ₁, θ₂, θ₃ . . . θₘ, where m is the number of the different measurement incident angles, and the adjustable range of the incident angle is 5-25°. The corresponding reflected light intensity is measured using the first detector (210) (I_{rθ}_{₁}, I_{rθ}_{₂}, I_{rθ}_{₃} . . . I_{rθ}_{ₘ}, where m is the number of the different measurement incident angles, and the adjustable range of the incident angle is 5-25°. The reflectivity of the pellicle (204) at these different incident angles is calculated as I_{rθ}_{ₘ}/I₀); the corresponding transmitted light intensity is measured using the second detector (213) □I_{tθ}_{₁}, I_{tθ}_{₂}, I_{tθ}_{₃} . . . I_{tθ}_{ₘ}□where m is the number of the different measurement incident angles), and the transmissivity at these different incident angles is calculated as I_{tθ}_{ₘ}/I₀□□For the transmissivity measurement of pellicle 604, under a certain angle of incidence, along the direction of the inspection light propagation, the third detector 610 is placed behind the pellicle 604. By means of the second electric slide 611, the transmitted light enters the effective inspection position of the third detector 610. By rotating the electric rotating displacement table 609, the angle of incidence of the inspection light on the pellicle 604 is changed. For the transmissivity test of pellicle, when the angle of incidence is changed, the position of the third detector 610 remains unchanged to complete the measurement of the transmitted light intensity of pellicle 604 at different angles of incidence, and the adjustable angle range is 5-25°. The transmissivity measurement of pellicle is specifically as follows: first, without placing the pellicle, the light intensity measured by the third detector 610 is I₀. Then the pellicle 604 is fixed on the pellicle holder 605. The pellicle holder 605 is fixed on the first electric three-axis displacement table 606. By means of the first electric three-axis displacement table 606, the position of the pellicle 604 is adjusted so that the inspection light irradiates the position of the pellicle to be detected. Each time the pellicle position is adjusted, it is necessary to ensure that the position of the pellicle irradiated by the inspection light is on the rotation axis of the electric rotating displacement table 609. The pellicle 604 is rotated by the electric rotating displacement table 609 to obtain the required angle of incidence (θ₀). Under these conditions, the transmissivity of the pellicle is calculated as Iₜ_{₀}/I₀. By using the first electric three-axis displacement table 606 to irradiate different positions of the pellicle 604, each time the pellicle position is adjusted, it is necessary to ensure that the position of the pellicle irradiated by the inspection light is on the rotation axis of the electric rotating displacement table 609. The transmitted light intensity at different positions of the pellicle 604 is measured by the third detector 610. (Iₜ_{₁}, Iₜ_{₂}, Iₜ_{₃} . . . Iₜ_{ₙ}, where n is the number of the measurement position), the transmissivity at each position is calculated. (that is Iₜ_{ₙ}/I₀). Thus, the transmittance uniformity of pellicle 604 is obtained. By rotating the pellicle 604 using the electric rotating displacement table 609, different angles of incidence are achieved (θ₁, θ₂, θ₃ . . . θₘ, where m is the number of different measurement angles of incidence), the corresponding transmitted light intensity is measured by the third detector 610 (I_{tθ}_{₁}, I_{tθ}_{₂}, I_{tθ}_{₃} . . . I_{tθ}_{ₘ} where m is the number of different measurement angles of incidence), and the transmissivity of pellicle 604 at different angles of incidence is calculated. (that is I_{tθ}_{ₘ}/I₀). For the reflectivity measurement of pellicle 604, the position of the third detector 610 is controlled by the second electric slide 611, so that the reflected light after pellicle 604 enters the effective inspection position of the third detector 610. The third detector 610 measures the corresponding reflected light intensity of pellicle 604 at different angles of incidence. (I_{rθ}_{₁}, I_{rθ}_{₂}, I_{rθ}_{₃} . . . I_{rθ}_{ₘ}, where m is the number of different measurement angles of incidence), and the reflectivity at different angles of incidence is calculated. (that is I_{rθ}_{ₘ}/I₀). FIG. 7 is a schematic diagram of the second mode of the pellicle transmissivity, transmittance uniformity, and reflectivity measurement module of the pellicle inspection device for extreme ultraviolet lithography masks in the present invention (the light source transmission is a toroidal mirror, and the second mode of the module for detecting the impact of contaminants on mask imaging). Considering that the transfer of the mask pattern to the photoresist is also related to the type of photoresist and subsequent processes such as development, post-baking temperature and time, compared with FIG. 6, FIG. 7 is the same as FIG. 6 in the working process of other modules except for the contaminant imaging module, comprising the projection optical system 715 and the wafer 716 coated with photoresist.

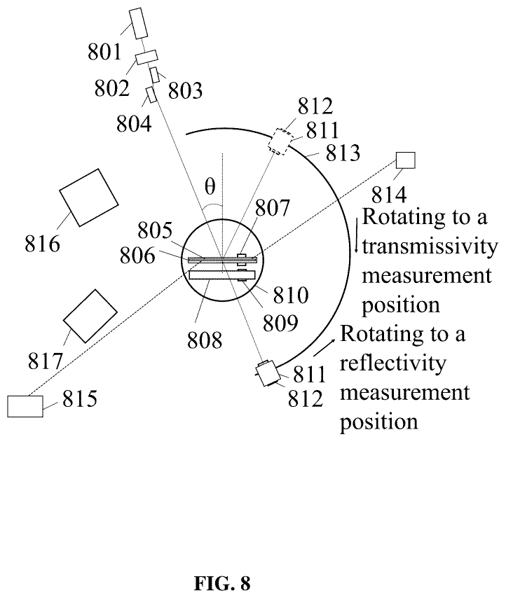

FIG. 8 is a schematic diagram of the second mode of the pellicle transmissivity, transmittance uniformity, and reflectivity measurement module of the pellicle inspection device for extreme ultraviolet lithography masks in the present invention (the light source transmission is two cylindrical mirrors, and the first mode of the module for detecting the impact of contaminants on mask imaging). Considering the processing difficulty and cost of the toroidal mirror 603 in the light source transmission in FIG. 6, compared with FIG. 6, FIG. 8 is the same as FIG. 6 in the working process of other modules except that the light source transmission uses two cylindrical mirrors, namely the first cylindrical mirror 803 and the second cylindrical mirror 804.

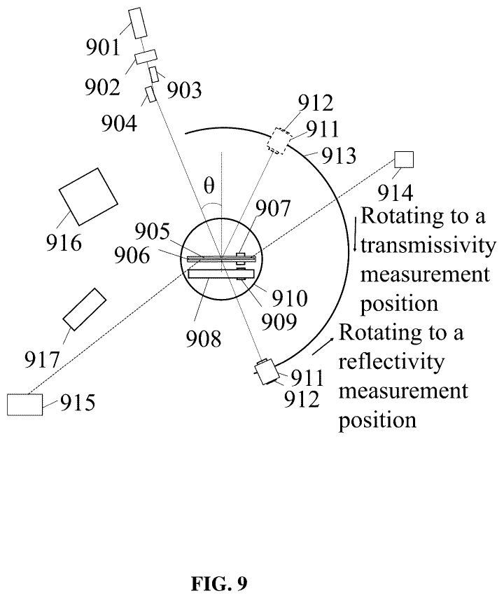

FIG. 9 is a schematic diagram of the second mode of the pellicle transmissivity, transmittance uniformity, and reflectivity measurement module of the pellicle inspection device for extreme ultraviolet lithography masks in the present invention (the light source transmission is two cylindrical mirrors, and the second mode of the module for detecting the impact of contaminants on mask imaging). Considering the processing difficulty and cost of the toroidal mirror 703 in the light source transmission in FIG. 7, compared with FIG. 7, FIG. 9 is the same as FIG. 7 in the working process of other modules except that the light source transmission uses two cylindrical mirrors, namely the first cylindrical mirror 903 and the second cylindrical mirror 904.

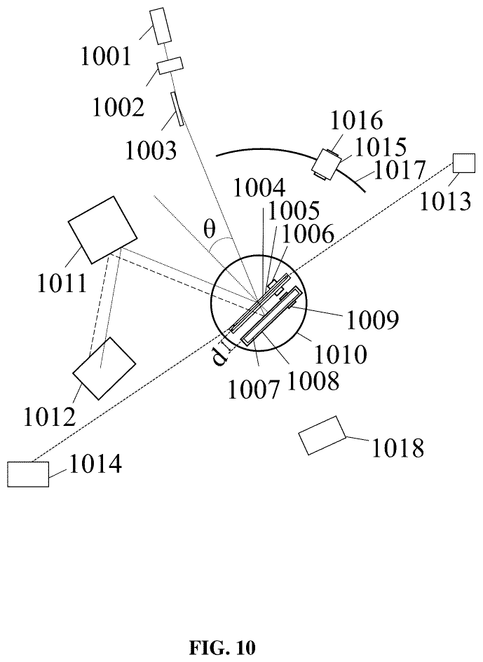

FIG. 10 is a schematic diagram of the first mode of the module for detecting the impact of contaminants on mask imaging of the pellicle inspection device for extreme ultraviolet lithography masks in the present invention (the light source transmission is a toroidal mirror, and the first mode of the pellicle transmissivity, transmittance uniformity, and reflectivity measurement module).

The pellicle 1004 is rotated by the electric rotating displacement table 1010 to switch from the pellicle transmissivity, transmittance uniformity, and reflectivity measurement module to the contaminant imaging module. The mask 1007 is fixed to the mask holder 1008. Specifically, the pellicle 1004 and the mask 1007 are rotated by the electric rotating displacement table 1010 to obtain the required angle of incidence (θ), at this angle of incidence, the mask imaging is optimal, and the inspection is carried out at this angle of incidence.

The working process of the device is as follows: the extreme ultraviolet (EUV) light source 1001 passes through the EUV irradiation time control electronic shutter 1002 to reach the light source transmission of the inspection light, namely the toroidal mirror 1003, and then is transmitted to the pellicle 1004 and the mask 1007. The pellicle 1004 is fixed on the pellicle holder 1005, which is fixed on the first electric three-axis displacement table 1006, and the first electric three-axis displacement table 1006 is fixed on the electric rotating displacement table 1010. The mask 1007 is fixed on the mask holder 1008, which is fixed on the second electric three-axis displacement table 1009, and the second electric three-axis displacement table 1009 is fixed on the electric rotating displacement table 1010.

The module for detecting the impact of contaminants on mask imaging comprises the projection optical system 1011 and the EUV camera 1012, which are used to obtain the mask pattern and its defect diffraction signals. Contaminants of different types and sizes with dimensions below 50 μm are introduced on the pellicle 1004 to study the impact of different types and sizes of contaminants on mask imaging. The position of the pellicle holder 1005 is changed by the first electric three-axis displacement table 1006, thereby adjusting the position of the pellicle 1004 and changing the distance (d) between the pellicle 1004 and the mask 1007 to study the impact of contaminants on mask imaging under different d values and to determine the optimal distance between the pellicle and the mask.

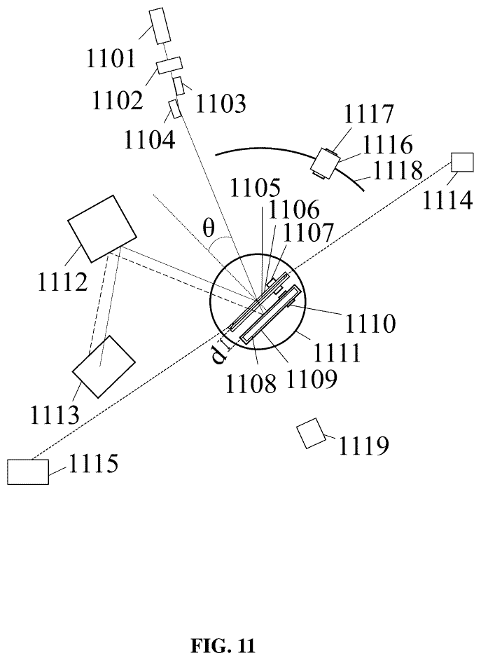

FIG. 11 is a schematic diagram of the first mode of the module for detecting the impact of contaminants on mask imaging of the pellicle inspection device for extreme ultraviolet lithography masks in the present invention (the light source transmission is two cylindrical mirrors, and the first mode of the pellicle transmissivity, transmittance uniformity, and reflectivity measurement module). Considering the processing difficulty and cost of the toroidal mirror 1003 in the light source transmission in FIG. 10, compared with FIG. 10, FIG. 11 is the same as FIG. 10 in the working process of other modules except that the light source transmission uses two cylindrical mirrors, namely the first cylindrical mirror 1103 and the second cylindrical mirror 1104.

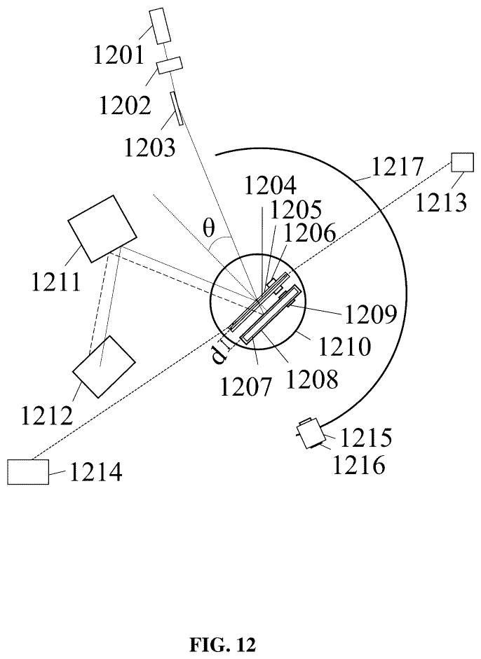

FIG. 12 is a schematic diagram of the first mode of the module for detecting the impact of contaminants on mask imaging of the pellicle inspection device for extreme ultraviolet lithography masks in the present invention (the light source transmission is a toroidal mirror, and the second mode of the pellicle transmissivity, transmittance uniformity, and reflectivity measurement module). Considering that FIG. 10 uses two detectors, namely the first detector 1015 and the second detector 1018, compared with FIG. 10, FIG. 12 uses one detector in the pellicle transmissivity, transmittance uniformity, and reflectivity measurement module, namely the third detector 1215, to complete the measurement of the transmissivity or reflectivity of pellicle 1204. The working process of other modules is the same as that in FIG. 10.

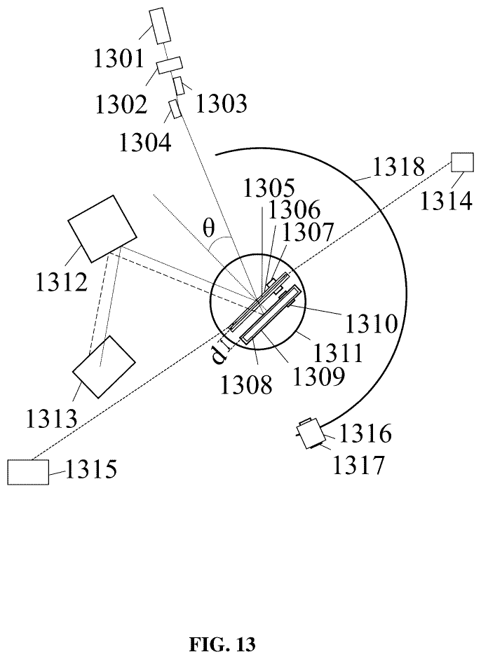

FIG. 13 is a schematic diagram of the first mode of the module for detecting the impact of contaminants on mask imaging of the pellicle inspection device for extreme ultraviolet lithography masks in the present invention (the light source transmission is two cylindrical mirrors, and the second mode of the pellicle transmissivity, transmittance uniformity, and reflectivity measurement module). Considering the processing difficulty and cost of the toroidal mirror 1203 in the light source transmission in FIG. 12, compared with FIG. 12, FIG. 13 is the same as FIG. 12 in the working process of other modules except that the light source transmission uses two cylindrical mirrors, namely the first cylindrical mirror 1303 and the second cylindrical mirror 1304.

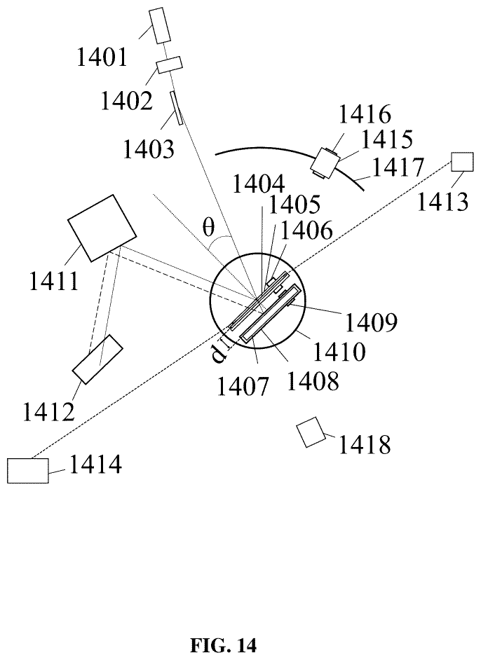

FIG. 14 is a schematic diagram of the second mode of the module for detecting the impact of contaminants on mask imaging of the pellicle inspection device for extreme ultraviolet lithography masks in the present invention (the light source transmission is a toroidal mirror, and the first mode of the pellicle reflectivity, transmittance uniformity, and reflectivity measurement module). Considering that the transfer of the mask pattern to the photoresist is also related to the type of photoresist and subsequent processes such as development, post-baking temperature and time, compared with FIG. 10, FIG. 14 comprises the projection optical system 1411 and the wafer 1412 coated with photoresist in the module for detecting the impact of contaminants on mask imaging; after EUV exposure, the photoresist is developed, and the developed pattern is characterized and analyzed by scanning electron microscopy or atomic force microscopy to determine the impact of contaminants on the mask exposure pattern, comprising the type of defects, the number of defects, line width, line width roughness and line edge roughness. The working process of other modules is the same as that in FIG. 10.

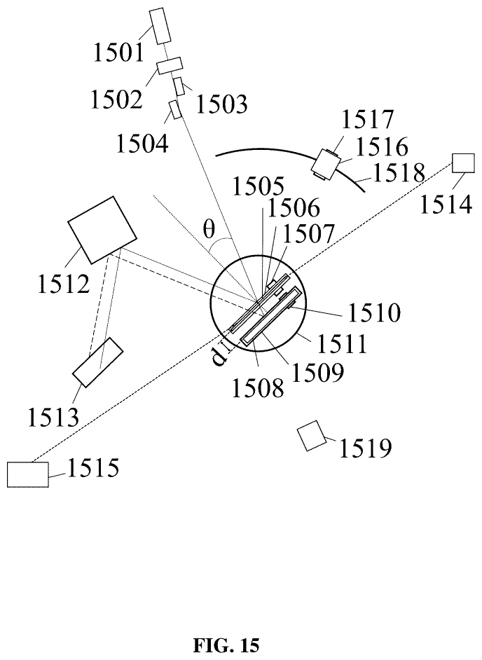

FIG. 15 is a schematic diagram of the second mode of the module for detecting the impact of contaminants on mask imaging of the pellicle inspection device for extreme ultraviolet lithography masks in the present invention (the light source transmission is two cylindrical mirrors, and the first mode of the pellicle transmissivity, transmittance uniformity, and reflectivity measurement module). Considering that the transfer of the mask pattern to the photoresist is also related to the type of photoresist and subsequent processes such as development, post-baking temperature and time, compared with FIG. 11, FIG. 15 comprises the projection optical system 1512 and the wafer 1513 coated with photoresist in the module for detecting the impact of contaminants on mask imaging; after EUV exposure, the photoresist is developed, and the developed pattern is characterized and analyzed by scanning electron microscopy or atomic force microscopy to determine the impact of contaminants on the mask exposure pattern, comprising the type of defects, the number of defects, line width, line width roughness and line edge roughness. The working process of other modules is the same as that in FIG. 11.

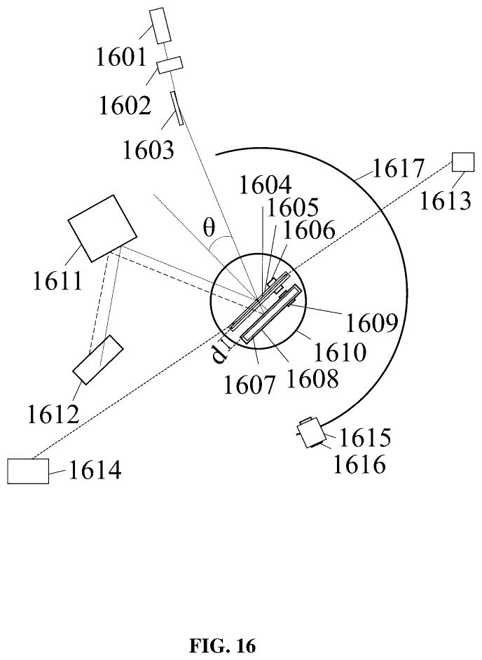

FIG. 16 is a schematic diagram of the second mode of the module for detecting the impact of contaminants on mask imaging of the pellicle inspection device for extreme ultraviolet lithography masks in the present invention (the light source transmission is a toroidal mirror, and the second mode of the pellicle transmissivity, transmittance uniformity, and reflectivity measurement module). Considering that the transfer of the mask pattern to the photoresist is also related to the type of photoresist and subsequent processes such as development, post-baking temperature and time, compared with FIG. 12, FIG. 16 comprises the projection optical system 1611 and the wafer 1612 coated with photoresist in the module for detecting the impact of contaminants on mask imaging; after EUV exposure, the photoresist is developed, and the developed pattern is characterized and analyzed by scanning electron microscopy or atomic force microscopy to determine the impact of contaminants on the mask exposure pattern, comprising the type of defects, the number of defects, line width, line width roughness and line edge roughness. The working process of other modules is the same as that in FIG. 12.

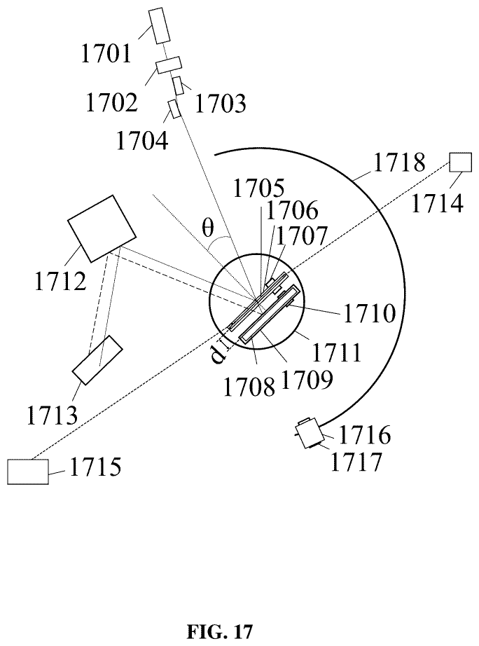

FIG. 17 is a schematic diagram of the second mode of the module for detecting the impact of contaminants on mask imaging of the pellicle inspection device for extreme ultraviolet lithography masks in the present invention (the light source transmission is two cylindrical mirrors, and the second mode of the pellicle transmissivity, transmittance uniformity, and reflectivity measurement module). Considering that the transfer of the mask pattern to the photoresist is also related to the type of photoresist and subsequent processes such as development, post-baking temperature and time, compared with FIG. 13, FIG. 17 comprises the projection optical system 1712 and the wafer 1713 coated with photoresist in the module for detecting the impact of contaminants on mask imaging; after EUV exposure, the photoresist is developed, and the developed pattern is characterized and analyzed by scanning electron microscopy or atomic force microscopy to determine the impact of contaminants on the mask exposure pattern, comprising the type of defects, the number of defects, line width, line width roughness and line edge roughness. The working process of other modules is the same as that in FIG. 13.

The present invention provides a pellicle inspection device for extreme ultraviolet lithography masks. It is used to study the impact of different types and sizes of contaminants on mask imaging and to optimize the distance between the pellicle and the mask. By rotating the sample, the module for detecting the impact of contaminants on mask imaging and the module for measuring the pellicle transmissivity, transmittance uniformity, and reflectivity can be quickly and efficiently switched. It can complete the measurement of pellicle transmissivity, transmittance uniformity, and reflectivity at different angles of incidence, with an adjustable angle range of 5° to 25°. The chemical changes of the pellicle under EUV irradiation, comprising the chemical reaction between the pellicle and hydrogen, are detected by mass spectrometry and/or Raman spectroscopy. It can simultaneously detect the optical properties of the pellicle (i.e., transmissivity, transmittance uniformity, and reflectivity) and the chemical reaction changes in this process, thereby studying the impact of the chemical changes of the pellicle under EUV irradiation on the optical properties of the pellicle. In addition to this, the system of the pellicle inspection device for extreme ultraviolet lithography masks in the present invention comprises but is not limited to the above structure, and it comprises all combinations that can produce the same optical path.

We claim:

1. An extreme ultraviolet lithography mask pellicle inspection device, comprising:
a inspection light source module configured to generate an extreme ultraviolet light source for inspection with a wavelength being within an extreme ultraviolet band and equipped with an extreme ultraviolet irradiation time control electronic shutter for controlling an irradiation time and a light source transmission system;
a sample platform module disposed in a vacuum chamber and configured to fix, move and rotating a to-be-detected pellicle and mask sample so as to ensure that the extreme ultraviolet light source achieves irradiation on different positions and at different incident angles, wherein an adjustable range of a distance between a pellicle and a mask is 1 mm to 10 mm;
a module for detecting the impact of contaminants on the pellicle on mask imaging, configured to study influences of different types and sizes of contaminants smaller than 50 μm and the distance between the pellicle and the mask on the mask imaging and determine an optimal distance;
a module for measuring a transmissivity, transmission uniformity, and reflectivity of the pellicle, configured to measure optical properties of the pellicle at the different incident angles and study influences of chemical changes of the pellicle on the optical properties thereof; wherein an adjustable range of the incident angles is 5° to 25°; wherein
as for detection for the influences of the contaminants on the pellicle on the mask imaging, the sample is the pellicle and the mask, the pellicle and the mask are placed on the sample platform module at the same time to achieve synchronous fixation, movement and rotation of the pellicle and the mask, the mask is placed behind the pellicle along a inspection light propagation direction, by controlling the rotation of an electric rotary displacement platform, the pellicle and the mask synchronously rotate to a preset incident angle to ensure that the mask imaging is optimal at the preset incident angle; by adjusting a first electric triaxial displacement platform, the distance between the pellicle and the mask is changed, an adjustable distance range is 1 to 10 mm, and the influences of the contaminants on the mask imaging under different distances between the pellicle and the mask are studied to obtain a relationship between the distance between the pellicle and the mask and the influences of the contaminants on the pellicle on the mask imaging, and the optimal distance between the pellicle and the mask is given; or,
as for measurement for the transmissivity, transmission uniformity, and reflectivity of the pellicle, the sample is the pellicle, the sample platform module is configured to fix, move and rotate the pellicle, an irradiation position of extreme ultraviolet light on the pellicle is always located on a rotating shaft of the electric rotary displacement platform, by rotating the electric rotary displacement platform, measurement for the different incident angles of the pellicle is achieved, an adjustable angle range is 5-25°, and by adjusting the first electric triaxial displacement platform, measurement for different positions of the pellicle is achieved;
the sample platform module comprises a pellicle fixing frame for placing the pellicle and a mask fixing frame for placing the mask, the pellicle fixing frame is controlled by the first electric triaxial displacement platform, the mask fixing frame is controlled by a second electric triaxial displacement platform, and the first electric triaxial displacement platform and the second electric triaxial displacement platform are both fixed on the electric rotary displacement platform and are sequentially placed along the inspection light propagation direction; the module for measuring a transmissivity, transmission uniformity, and reflectivity of the pellicle is divided into two modes according to a determination whether the transmissivity and the reflectivity can be measured at the same time:
in a first mode, transmitted beam energy and reflected beam energy are respectively measured by using two detectors to achieve the synchronous measurement of the transmissivity, transmission uniformity, and reflectivity of the pellicle, and a first detector, a second detector, a first arc guide rail and a first electric slide block are comprised; an axis of the first arc guide rail overlaps with an axis of the electric rotary displacement platform, a central angle of the first arc guide rail is 60°, the first detector is fixed on the first electric slide block, the first electric slide block is located on the first arc guide rail and is fixed in a reflected beam direction, by rotating the sample for an angle α, the first detector rotates for an angle 2α to detect the reflected beam energy, and 0°□α≤20°; the second detector is fixed in a transmitted beam direction, when no sample is placed, incident beam energy of a light source can be detected, when the sample is placed, the transmitted beam energy of the sample at the different incident angles is obtained by rotating the above-mentioned electric rotary displacement platform, the reflectivity of the pellicle is obtained according to a ratio of the reflected beam energy to the incident beam energy, the transmissivity of the pellicle is obtained according to a ratio of the transmitted beam energy to the incident beam energy, and a measurement position of the sample is changed by adjusting the first electric triaxial displacement platform to achieve multi-point-position transmissivity measurement of the pellicle, thereby obtaining the transmission uniformity of the pellicle;
in a second mode, a third detector, a second arc guide rail and a second electric slide block are comprised; a detector is reduced on the basis of the first mode, an axis of the second arc guide rail overlaps with the axis of the above-mentioned electric rotary displacement platform, a central angle of the second arc guide rail is 180°, and a measurement principle is consistent with that in the first mode. The transmitted beam energy and reflected beam energy are both detected by using the same detector, i.e., the third detector, and by rotating the third detector to positions of a transmitted beam and a reflected beam on the second arc guide rail, the transmissivity, the transmission uniformity, and the reflectivity of the pellicle are respectively measured.

2. The extreme ultraviolet lithography mask pellicle inspection device of claim 1, wherein the light source transmission system comprises a toroidal mirror or two cylindrical mirrors.

3. The extreme ultraviolet lithography mask pellicle inspection device of claim 1, wherein the module for detecting the impact of contaminants on the pellicle on mask imaging is divided into two modes according to inspection purposes;
in a first mode, a mask pattern and a defect diffraction signal thereof are obtained, and a projection optical system and an extreme ultraviolet camera are comprised; and
in a second mode, a photoresist is exposed and developed by the above-mentioned inspection light source module, the developed pattern is represented by a scanning electron microscope or an atomic force microscope, and influences of the contaminants on the masked and exposed pattern are analyzed, wherein the influences comprise types of generated defects, the number of the defects, a line width, the roughness of the line width and the roughness of a line edge, and the projection optical system and a photoresist-coated wafer are comprised.

4. The extreme ultraviolet lithography mask pellicle inspection device of claim 1, wherein by controlling the rotation of the sample by means of the above-mentioned electric rotary displacement platform, the switching between the module for detecting the impact of contaminants on the pellicle on mask imaging and the module for measuring a transmissivity, transmission uniformity, and reflectivity of the pellicle.

5. The extreme ultraviolet lithography mask pellicle inspection device of claim 1, further comprising:
a hydrogen production module configured to produce hydrogen and control a hydrogen partial pressure in the vacuum chamber, wherein an adjustable range is 0 to 10 Pa; and
a chemical detection and analysis module configured to study changes of a chemical reaction between the pellicle and the hydrogen under extreme ultraviolet irradiation by using a mass spectrometry and/or Raman spectroscopy.
